(19) United States
(12) Patent Application Publication
(10) Pub. No.: US 2017/0253964 A1
(43) Pub. Date: Sep. 7, 2017

(54) FILM DEPOSITION METHOD

(71) Applicant: Tokyo Electron Limited, Tokyo (JP)

(72) Inventors: Hitoshi KATO, Iwate (JP); Masahiro MURATA, Iwate (JP); Jun SATO, Iwate (JP); Shigehiro MIURA, Iwate (JP)

(21) Appl. No.: 15/439,180

(22) Filed: Feb. 22, 2017

(30) Foreign Application Priority Data
Mar. 2, 2016 (JP) 2016-040217

(51) Int. Cl. C23C 16/34; C23C 16/455; C23C 16/50; C23C 16/24

(52) U.S. Cl. CPC C23C 16/345; C23C 16/24; C23C 16/45525; C23C 16/50

(57) ABSTRACT

A film deposition method includes steps of: adsorbing a silicon-containing gas on a surface of a substrate, by supplying the silicon-containing gas to the surface of the substrate; depositing a silicon nitride film, by supplying a nitriding gas to the surface of the substrate, while being activated by a first plasma, and nitriding the silicon-containing gas adsorbed on the surface of the substrate; and modifying the silicon nitride film deposited on the surface of the substrate, by supplying a treatment gas containing NH₃ and N₂ at a given ratio to the surface of the substrate, while being activated by a second plasma.

### CROSS-REFERENCE TO RELATED APPLICATIONS

The present application claims priority under 35 U.S.C. §119 to Japanese Patent Application No. 2016-40217 filed on Mar. 2, 2016, the entire contents of which are incorporated herein by reference.

### BACKGROUND OF THE INVENTION

1. Field of the Invention

The disclosures herein generally relate to a film deposition method.

2. Description of the Related Art

Regarding a film deposition method with Atomic Layer Deposition (ALD), as described in Japanese Laid-Open Patent Application Publication No. 2015-165549, the film deposition method for film deposition using a film deposition apparatus in which two plasma generators are installed has conventionally been known.

The film deposition apparatus described in Japanese Laid-Open Patent Application Publication No. 2015-165549 includes a turntable in a vacuum chamber, so that a substrate can be mounted on the turntable. The film deposition apparatus includes a first process gas supply unit that supplies a first process gas on the surface of the substrate, a first plasma processing gas supply unit that supplies a first plasma processing gas, and a second plasma processing gas supply unit that supplies a second plasma processing gas. The film deposition apparatus further includes a first plasma generator that converts the first plasma processing gas to plasma, and a second plasma generator that converts the second plasma processing gas to plasma. The distance between the second plasma generator and the turntable is set shorter than the distance between the first plasma generator and the turntable. With such a configuration, ion energy and radical concentration of the second plasma processing gas can be made higher than ion energy and radical concentration of the first plasma processing gas.

By using the film deposition apparatus with such a configuration, a silicon-containing gas is supplied from the first process gas supply unit, NH₃ is supplied from the first plasma processing gas supply unit, and a mixed gas of NH₃, Ar, and H₂ is supplied from the second plasma processing gas supply unit. The silicon-containing gas adsorbed on the substrate can be nitrided by NH₃ that is low in ion energy and radical concentration, and can be modified by the mixed gas of NH₃, Ar, and H₂ that is low in ion energy and radical concentration, so that generation of a so-called loading effect, in which a film deposition amount across the surface of the wafer changes depending on the surface area of the pattern, can be prevented.

### SUMMARY OF THE INVENTION

The present disclosure has an object of providing a film deposition method capable of improving uniformity across the surface of the wafer.

In order to achieve the above object, according to an embodiment of the present application, a film deposition method includes steps of: adsorbing a silicon-containing gas on a surface of a substrate, by supplying the silicon-containing gas to the surface of the substrate; depositing a silicon nitride film, by supplying a nitriding gas to the surface of the substrate, while being activated by a first plasma, and nitriding the silicon-containing gas adsorbed on the surface of the substrate; and modifying the silicon nitride film deposited on the surface of the substrate, by supplying a treatment gas containing NH₃ and N₂ at a given ratio to the surface of the substrate, while being activated by a second plasma.

### BRIEF DESCRIPTION OF THE DRAWINGS

FIG. 1 is a schematic vertical cross-sectional view illustrating an example of a film deposition apparatus preferable to implement a film deposition method according to an embodiment of the present disclosure;

FIG. 2 is a schematic plan view illustrating an example of a film deposition apparatus of FIG. 1;

FIG. 3 illustrates a cross-sectional view cut along a concentric circle of a turntable of the film deposition apparatus;

FIG. 4 illustrates a vertical cross-sectional view of an example of the plasma generators;

FIG. 5 illustrates an exploded perspective view of an example of the plasma generators;

FIG. 6 illustrates a perspective view of an example of a housing provided in the plasma generators;

FIG. 7 illustrates a plan view of an example of the plasma generator of the film deposition apparatus of FIG. 1;

FIG. 8 illustrates a perspective view of a part of a Faraday shield provided in the plasma generator;

FIG. 9 is a diagram showing results, in which film deposition methods in working examples 1 to 5, a comparative example, and a reference example were performed, on a lateral axis passing through the center of a wafer approximately parallel to a rotational direction of the turntable;

FIG. 10 is a diagram showing results, in which the film deposition methods in the working examples 1 to 5, the comparative example, and the reference example were performed, on Y axis that is a vertical axis passing through the center of the wafer approximately parallel to the radial direction of the turntable;

FIG. 11 is a diagram showing results, in which the film deposition methods in the working examples 1 to 6, the comparative example, and the reference example were performed, from a viewpoint of uniformity across the surface of the wafer;

FIG. 12 is a diagram showing calculation results of the uniformity of a SiN film deposited on the wafer in the working examples 1 to 6, the comparative example, and the reference example;

FIG. 13 is a diagram showing results of film thickness distributions on X axis in the working example 4 and the comparative example; and

FIG. 14 is a diagram showing results of film thickness distributions on Y axis in the working example 4 and the comparative example.

### DESCRIPTION OF THE PREFERRED EMBODIMENTS

In the following, embodiments of the present disclosure will be described.

[Configuration of Film Deposition Apparatus]

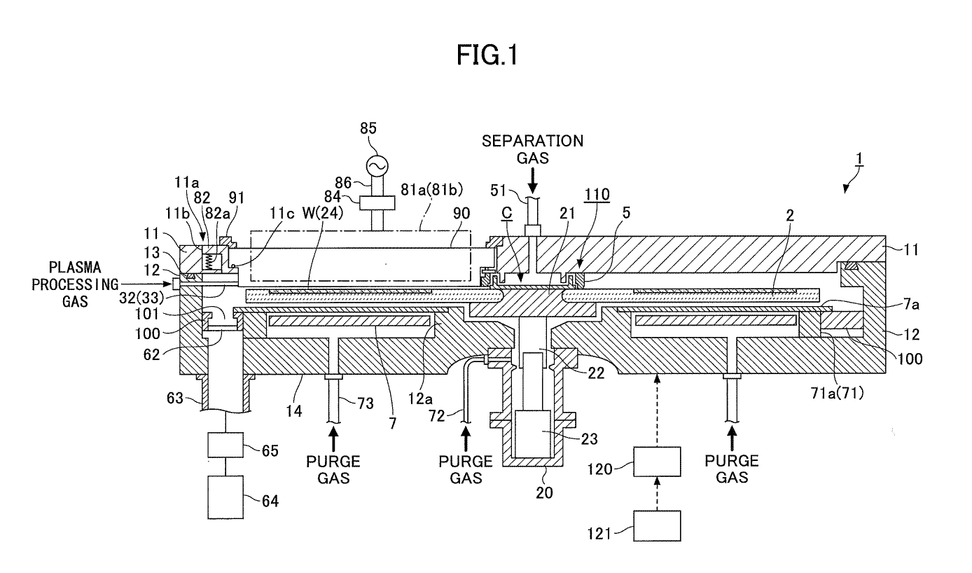

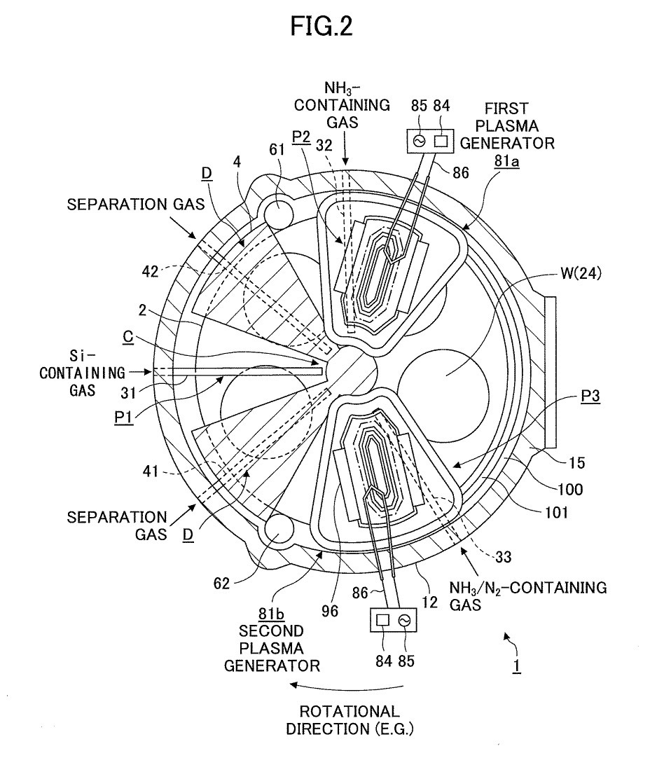

FIG. 1 is a schematic vertical cross-sectional view illustrating an example of a film deposition apparatus preferable to implement a film deposition method according to an embodiment of the present disclosure. FIG. 2 is a schematic plan view illustrating an example of a film deposition apparatus to implement the film deposition method according to an embodiment of the present disclosure. Here, in FIG. 2, a depiction of a ceiling plate 11 is omitted for the purpose of illustration.

As illustrated in FIG. 1, the film deposition apparatus to implement the film deposition method according to an embodiment includes a vacuum chamber 1 having an approximately circular planar shape and a turntable 2 provided in the vacuum chamber 1 and having its rotational center that coincides with the center of the vacuum chamber 1 to rotate a wafer W placed thereon.

The vacuum chamber 1 is a process chamber for processing a substrate therein. The vacuum chamber 1 includes a ceiling plate (ceiling part) 11 provided in a position facing concave portions 24 of the turntable 2 that will be described later and a chamber body 12. Moreover, a seal member 13 having a ring-like shape is provided in a periphery in an upper surface of the chamber body 12. The ceiling plate 11 is configured to be detachable from the chamber body 12. A diameter dimension (inner diameter dimension) of the vacuum chamber 1 when seen in a plan view is not limited, but can be, for example, set at about 1100 mm.

A separation gas supply pipe 51 is connected to a central part in an upper surface of the ceiling plate 11 and is further in communication with a central part of an upper surface side in the vacuum chamber 1 through a hole to supply a separation gas for preventing different process gases from mixing with each other in a central area C.

The turntable 2 is fixed to a core portion 21 having an approximately cylindrical shape at the central part, and is configured to be rotatable by a drive unit 23 in a clockwise fashion as illustrated in FIG. 2 as an example, around a rotational shaft 22 connected to a lower surface of the core portion 21 and extending in a vertical direction, which forms a vertical axis. The diameter dimension of the turntable 2 is not limited, but can be set at, for example, about 1000 mm.

The rotational shaft 22 and the drive unit 23 are accommodated in a casing body 20, and a flange portion at an upper surface side of the casing body 20 is hermetically attached to a lower surface of a bottom portion 14 of the vacuum chamber 1. A purge gas supply pipe 72 for supplying nitrogen gas or the like as a purge gas (separation gas) is connected to an area below the turntable 2.

A peripheral side of the core portion 21 in a bottom part 14 of the vacuum chamber 1 forms a protruding part 12a by being formed into a ring-like shape so as to come to close to the lower surface of the turntable 2.

Circular concave portions 24 are formed in a surface of the turntable 2 as a substrate receiving area to receive wafers W each having a diameter dimension of, for example, 300 mm thereon. The concave portions 24 are provided at a plurality of locations, for example, at five locations along a rotational direction of the turntable 2. Each of the concave portions 24 has an inner diameter slightly larger than the diameter of the wafer W, more specifically, larger than the diameter of the wafer W by about 1 mm to 4 mm. Furthermore, the depth of each of the concave portions 24 is configured to be approximately equal to or greater than the thickness of the wafer W. Accordingly, when the wafer W is accommodated in the concave portion 24, the surface of the wafer W is as high as, or lower than a surface of the turntable 2 where the wafer W is not placed. Here, even when the depth of each of the concave portions 24 is greater than the thickness of the wafer W, the depth of each of the concave portions 24 is preferably equal to or smaller than about three times the thickness of the wafer W, because too deep concave portions 24 may affect the film deposition.

Here, a recessed pattern such as a trench or a via hole is formed in a surface of the wafer W. The film deposition method according to an embodiment is a method preferable for filling any recessed pattern with a film. Hence, the film deposition method according to an embodiment can be preferably applied to the film deposition for filling the recessed pattern such as the trench and the via hole formed in the surface of the wafer W.

Through holes not illustrated in the drawings are formed in a bottom surface of the concave portion 24 to allow, for example, three lifting pins that will be described later to push up the wafer W from below and to lift the wafer W.

As illustrated in FIG. 2, for example, five nozzles 31, 32, 33, 41, and 42 each made of, for example, quartz are arranged in a radial fashion at intervals in the circumferential direction of the vacuum chamber 1 at respective positions opposite to a passing area of the concave portions 24. Each of the nozzles 31, 32, 33, 41, and 42 is arranged between the turntable 2 and the ceiling plate 11. These nozzles 31, 32, 33, 41, and 42 are each installed, for example, so as to horizontally extend facing the wafer W from, for example, an outer peripheral wall of the vacuum chamber 1 toward the central area C.

In the example illustrated in FIG. 2, a source gas nozzle 31, a separation gas nozzle 42, a first plasma processing gas nozzle 32, a second plasma processing gas nozzle 33, and a separation gas nozzle 41 are arranged in a clockwise fashion (in the rotational direction of the turntable 2) in this order. However, the film deposition apparatus of one or more embodiments is not limited to this form, and the turntable 2 may rotate in a counterclockwise fashion. In this case, the source gas nozzle 31, the separation gas nozzle 42, the first plasma processing gas nozzle 32, the second plasma processing gas nozzle 33, and the separation gas nozzle 41 are arranged in this order in the counterclockwise fashion.

As illustrated in FIG. 2, plasma generators 81a and 81b are provided above the first plasma processing gas nozzle 32 and the second plasma processing gas nozzle 33, respectively, to convert plasma processing gases discharged from the respective plasma processing gas nozzles 32 and 33 to plasma. The plasma generators 81a and 81b will be described later.

Here, in an embodiment, although an example of arranging a single nozzle in each process area is illustrated, a configuration of providing a plurality of nozzles in each process area is also possible. For example, the first plasma processing gas nozzle 32 may be constituted of a plurality of plasma processing gas nozzles, each of which is configured to supply argon (Ar) gas, ammonia (NH₃) gas, hydrogen (H₂) gas or the like, or may be constituted of only a single plasma processing gas nozzle configured to supply a mixed gas of argon gas, ammonia gas, and hydrogen gas.

The source gas nozzle 31 forms a source process gas supply unit. Moreover, the first plasma processing gas nozzle 32 forms a first plasma processing gas supply unit, and the second plasma processing gas nozzle 33 forms a second plasma processing gas supply unit. Furthermore, each of the separation gas nozzles 41 and 42 forms a separation gas supply unit. Here, the separation gas may be referred to as a purge gas as described above.

Each of the nozzles 31, 32, 33, 41, and 42 is connected to each gas supply source not illustrated in the drawings through a flow control valve.

A source gas supplied from the source gas nozzle 31 is a silicon-containing gas. As an example of the silicon-containing gas, DCS [dichlorosilane], disilane (Si₂H₆), HCD [hexachlorodisilane], DIPAS [diisopropylamino-silane], 3DMAS [tris(dimethylamino)silane], BTBAS [bis(tertiary-butyl-amino)silane], and the like are cited.

Also, a metal-containing gas may be used as an example of the source gas supplied from the source gas nozzle 31, other than the silicon-containing gas, such as TiCl₄ [titanium tetrachloride], Ti(MPD)(THD) [titanium methylpentanedionato bis(tetramethylheptanedionato)], TMA [trimethylaluminium], TEMAZ [tetrakis(ethylmethylamino)zirconium], TEMHF [tetrakis(ethylmethylamino)hafnium], Sr(THD)₂ [strontium bis(tetramethylheptanedionato)] or the like.

An ammonia (NH₃) containing gas, which is a nitriding gas, is selected as the first plasma processing gases supplied from the first plasma processing gas nozzle 32. By using NH₃, NH₂* serving as a nitriding source is supplied on the surface of the wafer W containing the recessed pattern, and the silicon-containing gas can be nitrided to deposit a molecular layer of SiN. Here, H₂ gas, Ar, and the like may be contained in addition to NH₃ gas, as necessary. The mixed gas of these gases is supplied from the first plasma processing gas nozzle 32, and is activated (ionized or radicalized) by plasma generated by the first plasma generator 81a.

An NH₃/N₂-containing gas that contains both NH₃ and N₂ is selected as the second plasma processing gas supplied from the second plasma processing gas nozzle 33 to improve a nitriding power of NH₃. By adding N₂ to NH₃, both NH₃ and N₂ can be generated and the nitriding power can be improved. Details of such a mechanism will be described later.

The NH₃/N₂-containing gas may contain an Ar gas, an H₂ gas and the like, as necessary, in addition to NH₃/N₂, and the mixed gas of these gasses may be supplied as the second plasma processing gas from the second plasma processing gas nozzle 32.

Thus, different gases are selected for the first plasma processing gas and the second plasma processing gas from each other, on the whole including composition ratios.

For example, nitrogen (N₂) gas is used as the separation gas supplied from the separation gas nozzles 41 and 42.

As discussed above, in the example illustrated in FIG. 2, the source gas nozzle 31, the separation gas nozzle 42, the first plasma processing gas nozzle 32, the second plasma processing gas nozzle 33, and the separation gas nozzle 41 are arranged in this order in a clockwise fashion (in the rotational direction of the turntable 2). In other words, in an actual process of the wafer W, the wafer W having the surface including the recessed pattern on which the Si-containing gas supplied from the source gas nozzle 31 is adsorbed is sequentially exposed to the separation gas from the separation gas nozzle 42, the plasma processing gas from the first plasma processing gas nozzle 32, the plasma processing gas from the second plasma processing gas nozzle 33, and the separation gas from the separation gas nozzle 41 in this order.

Gas discharge holes 35 for discharging each of the above-mentioned gases are formed in each lower surface (the surface facing the turntable 2) of the gas nozzles 31, 32, 33, 41, and 42 along a radial direction of the turntable 2 at a plurality of locations, for example, at regular intervals. Each of the nozzles 31, 32, 33, 41, and 42 is arranged so that a distance between a lower end surface of each of the nozzles 31, 32, 33, 41, and 42 and an upper surface of the turntable 2 is set at, for example, about 1 mm to 5 mm.

An area under the source gas nozzle 31 is a first process area P1 to cause the Si-containing gas to adsorb on the wafer W. An area under the first plasma processing gas nozzle 32 is a second process area P2 to perform a first plasma process on a thin film on the wafer W. An area under the second plasma processing gas nozzle 33 is a third process area P3 to perform a third plasma process on the thin film on the wafer W.

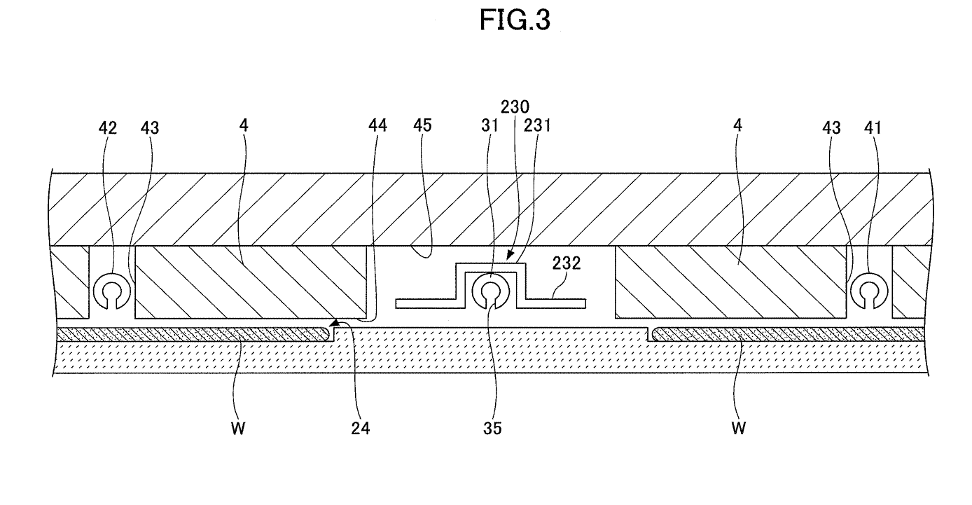

FIG. 3 illustrates a cross-sectional view cut along a concentric circle of the turntable 2 of the film deposition apparatus. Here, FIG. 3 illustrates the cross-sectional view from one of the separation area D to the other separation area D by way of the first process area P1.

Approximately sectorial convex portions 4 are provided on the ceiling plate 11 of the vacuum chamber 1 in the separation areas D. Flat low ceiling surfaces 44 (first ceiling surfaces) that are lower surfaces of the convex portions 4, and ceiling surfaces 45 (second ceiling surfaces) that are higher than the ceiling surfaces 44 and that are provided on both sides of the ceiling surfaces 44 in a circumferential direction, are formed in the vacuum chamber 1.

As illustrated in FIG. 2, the convex portions 4 forming the ceiling surfaces 44 have a fan-like planar shape whose apexes are cut into an arc-like shape. Moreover, each of the convex portions 4 has a groove portion 43 formed so as to extend in the radial direction in the center in the circumferential direction, and each of the separation gas nozzles 41 and 42 is accommodated in the groove portion 43. Here, a periphery of each of the convex portions 4 (a location on the peripheral side of the vacuum chamber 1) is bent into an L-shaped form so as to face an outer edge surface of the turntable 2 and to be located slightly apart from the chamber body 12 in order to prevent each of the process gases from mixing with each other.

A nozzle cover 230 is provided on the upper side of the source gas nozzle 31 in order to cause the first process gas to flow along the wafer W and so as to cause the separation gas to flow through a location close to the ceiling plate 11 of the vacuum chamber 1 while flowing away from the neighborhood of the wafer W. As illustrated in FIG. 3, the nozzle cover 230 includes an approximately box-shaped cover body 231 whose lower surface side is open to accommodate the source gas nozzle 31, and current plates 232 having a plate-like shape and connected to the lower open ends of the cover body 231 on both upstream and downstream sides in the rotational direction of the turntable 2. Here, a side wall surface of the cover body 231 on the rotational center side of the turntable 2 extends toward the turntable 2 so as to face a tip of the source gas nozzle 31. In addition, the side wall surface of the cover body 231 on the peripheral side of the turntable 2 is cut off so as not to interfere with the sources gas nozzle 31.

Next, the first plasma generator 81a and the second plasma generator 81b respectively provided above the first and second plasma processing gas nozzles 32 and 33 are described below in detail. Here, in the present embodiment, although each of the first plasma generator 81a and the second plasma generator 81b can perform an independent plasma treatment, each structure can be the same as each other.

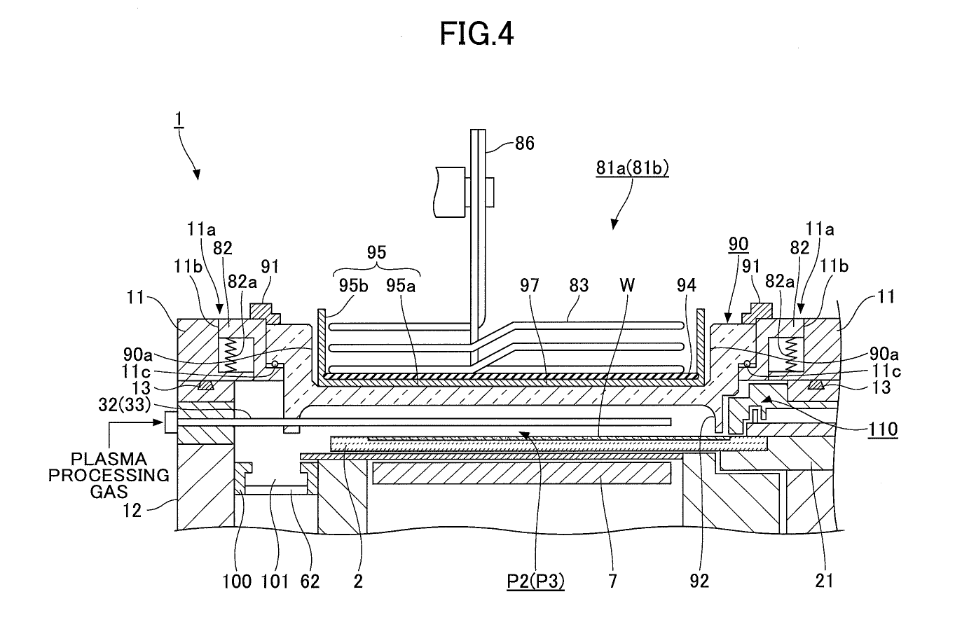

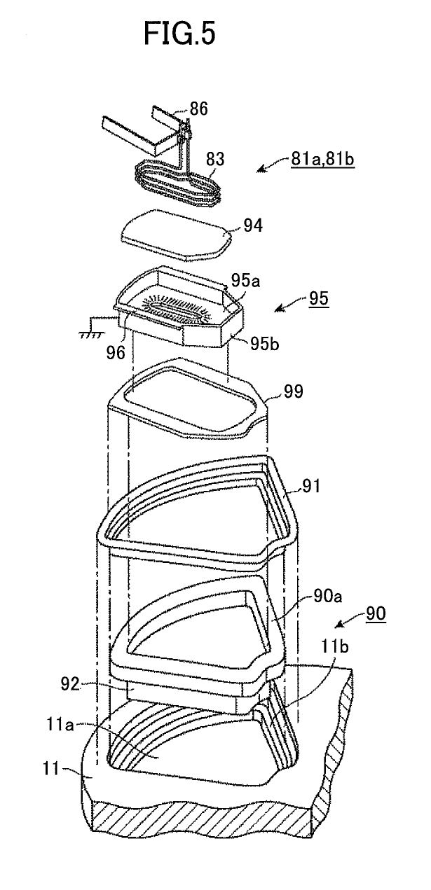

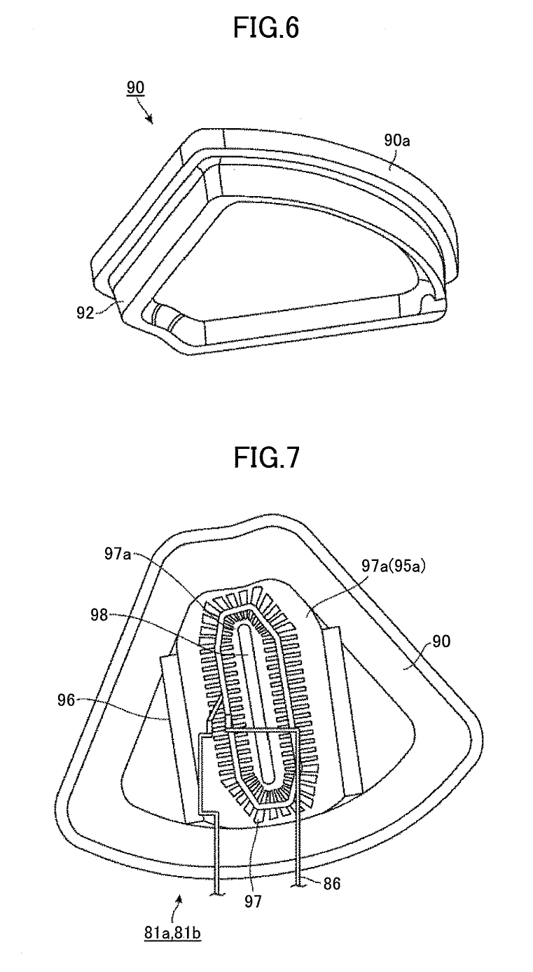

FIG. 4 illustrates a vertical cross-sectional view of an example of the plasma generators. Also, FIG. 5 illustrates an exploded perspective view of an example of the plasma generators. Furthermore, FIG. 6 illustrates a perspective view of an example of a housing provided in the plasma generators.

The plasma generators 81a and 81b are configured to wind an antenna 83 constituted of a metal wire or the like, for example, triply around the vertical axis. Moreover, each of the plasma generators 81a and 81b is arranged so as to surround a band area extending in the radial direction of the turntable 2 when seen in a plan view and to cross the diameter of the wafer W on the turntable 2.

The antenna 83 is, for example, connected to a radio frequency power source 85 having a frequency of 13.56 MHz and output power of 5000 W via a matching box 84. Then, the antenna 83 is provided to be hermetically separated from an inner area of the vacuum chamber 1. Here, in FIG. 4, a connection electrode 86 is provided to electrically connect the antenna 83 with the matching box 84 and the radio frequency power source 85.

As illustrated in FIGS. 4 and 5, an opening 11a having an approximately fan-like shape when seen in a plan view is formed in the ceiling plate 11 above the first plasma processing gas nozzle 32.

As illustrated in FIG. 4, an annular member 82 is hermetically provided in the opening 11a along the verge of the opening 11a. The housing 90 that will be described later is hermetically provided on the inner surface side of the annular member 82. In other words, the annular member 82 is hermetically provided at a position where the outer peripheral side of the annular member 82 faces the inner surface 11b of the opening 11a in the ceiling plate 11 and the inner peripheral side of the annular member 82 faces a flange part 90a of the housing 90 that will be described later. The housing 90 made of, for example, a derivative of quartz is provided in the opening 11a through the annular member 82 in order to arrange the antenna 83 at a position lower than the ceiling plate 11.

Moreover, as illustrated in FIG. 4, the annular member 82 includes a bellows 82a expandable in the vertical direction. Furthermore, the plasma generators 81a and 81b are formed to be able to move up and down independently of each other by a drive mechanism (elevating mechanism) not illustrated in the drawings, such as an electric actuator or the like. By causing the bellows 82a to extend and contract in response to the rise and fall of the plasma generators 81a and 81b, each distance between each of the plasma generators 81a and 81b and the wafer W (i.e., turntable 2) (which may be referred to as a distance of a plasma generation space, hereinafter) can be changed during the plasma treatment.

As illustrated in FIG. 6, the casing 90 is configured to have a peripheral part horizontally extending along the circumferential direction on the upper side so as to form the flange part 90a and a central part recessed toward the inner area of the vacuum chamber 1 when seen in a plan view.

The housing 90 is arranged to cross the diameter of the wafer W in the radial direction of the turntable 2 when the wafer W is located under the housing 90. Here, as illustrated in FIG. 4, a seal member 11c such as an O-ring or the like is provided between the annular member 82 and the ceiling plate 11.

An internal atmosphere of the vacuum chamber 1 is sealed by the annular member 82 and the housing 90. More specifically, the annular member 82 and the housing 90 are set in the opening 11a, and then the housing 90 is pressed downward through the whole circumference by a pressing member 91 formed into a frame-like shape along the contact portion of the annular member 82 and the housing 90. Furthermore, the pressing member 91 is fixed to the ceiling plate 11 by volts and the like not illustrated in the drawings. This causes the internal atmosphere of the vacuum chamber 1 to be sealed. Here, in FIG. 5, a depiction of the annular member 82 is omitted for simplification.

As illustrated in FIG. 6, a projection portion 92 vertically extending toward the turntable 2 is formed in a lower surface of the housing 90 so as to surround each of the second and third process areas P2 and P3 under the housing 90 along each circumferential direction thereof. Then, the first plasma processing gas nozzle 32 and the second plasma processing gas nozzle 33 are accommodated in an area surrounded by an inner circumferential surface of the projection portion 92, the lower surface of the housing 90, and the upper surface of the turntable 2. Here, the projection portion 92 at the base end portion (the inner wall side of the vacuum chamber 1) of each of the first plasma processing gas nozzle 32 and the second plasma processing gas nozzle 33 is cut off so as to be formed into an approximately arc-like shape along each of outer shapes of the first plasma processing gas nozzle 32 and the second plasma processing gas nozzle 33.

As illustrated in FIG. 4, the projection portion 92 is formed on the lower side of the housing 90 along the circumferential direction thereof. The seal member 11c is not directly exposed to the plasma due to the projection portion 92, and that is to say, is separated from the plasma generation space. Thus, even if the plasma is likely to diffuse, for example, to the seal member 11c side, because the plasma goes toward the seal member 11c by way of the lower side of the projection portion 92, the plasma becomes inactivated before reaching the seal member 11c.

A grounded Faraday shield 95 that is formed so as to approximately fit along an inner shape of the housing 90 and that is made of a conductive plate-like body, for example, a metal plate such as a copper plate and the like, is installed in the housing 90. The Faraday shield 95 includes a horizontal surface 95a horizontally formed along the bottom surface of the housing 90, and a vertical surface 95b extending upward from the outer edge of the horizontal surface 95a over the whole inner circumference of the housing 90, and may be configured to be approximately hexagonal when seen in a plan view.

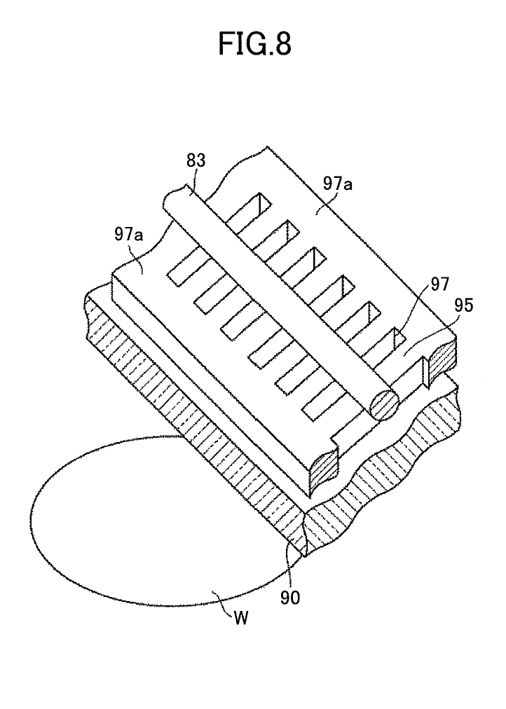

FIG. 7 illustrates a plan view of an example of the plasma generator according to an embodiment, and FIG. 8 illustrates a perspective view of a part of the Faraday shield provided in the plasma generator according to an embodiment.

Upper end edges of the Faraday shield 95 on the right side and the left side extend horizontally rightward and leftward, respectively, when seen from the rotational center of the turntable 2, and form supports 96. As illustrated in FIG. 5, a frame body 99 is provided between the Faraday shield 95 and the housing 90 to support the support 96 from below. The frame body 99 is supported by the flange part 90a of the housing 90 on the central area C and the outer periphery of the turntable 2.

When an electric field generated by the antenna 83 reaches the wafer W, a pattern (electrical wiring and the like) formed inside the wafer W may be electrically damaged. Accordingly, as illustrated in FIG. 8, many slits 97 are formed in the horizontal surface 95a in order to prevent an electric field component of the electric field and a magnetic field (i.e., an electromagnetic field) generated by the antenna 83 from going toward the wafer W located below and to allow the magnetic field to reach the wafer W.

As illustrated in FIGS. 7 and 8, the slits 97 are formed under the antenna 83 along the circumferential direction so as to extend in a direction perpendicular to a winding direction of the antenna 83. Here, the slits 97 are formed to have a width dimension equal to or less than about 1/10000 of a wavelength of the radio frequency power supplied to the antenna 83. Moreover, electrically conducting paths 97a made of a grounded electric conductor and the like are arranged on one end and the other end in a lengthwise direction of each of the slits 97 so as to stop open ends of the slits 97. An opening 98 is formed in an area out of the area where the slits 97 are formed in the Faraday shield 95. That is to say, the opening 98 is formed at the central side of the area, where the antenna 83 is wound around, to be able to observe a light emitting state of the plasma therethrough. Here, in FIG. 2, the slits 97 are omitted for simplicity, and an example of the slit formation area is expressed by alternate long and short dash lines.

As illustrated in FIG. 5, an insulating plate 94 made of quartz and the like having a thickness dimension of, for example, about 2 mm, is stacked on the horizontal surface 95a of each of the Faraday shields 95 in order to ensure insulation properties from the plasma generators 81a and 81b placed on each of the Faraday shields 95. In other words, each of the plasma generators 81a and 81b is arranged so as to face the inside of the vacuum chamber 1 (the wafer W on the turntable 2) through the housing 90, the Faraday shield 95, and the insulating plate 94.

Thus, the first plasma generator 81a and the second plasma generator 81b have structures similar to each other, but installed heights are different from each other. In other words, the distance between the surface of the turntable 2 and the first plasma generator 81a and the distance between the surface of the turntable 2 and the second plasma generator 81b are different from each other. The heights of the plasma generators 81a and 81b can be readily made different from each other by adjusting the heights of the housings 90.

More specifically, the height of the first plasma generator 81a is set higher than the height of the second plasma generator 81b. As discussed above, the second process area P2 substantially closed by the housing 90 is formed in an area under the first plasma generator 81a, and the third process area P3 substantially closed by the housing 90 is formed in an area under the second plasma generator 81b. Hence, one of the plasma generators 81a and 81b having the smaller distance from the surface of the turntable 2, or positioned lower than the other, forms a smaller space under the housing 90 than the other. Here, when the distance between the first plasma generator 81a and the surface of the turntable 2 in the second process area P2 is made a first distance, and when the distance between the second plasma generator 81b and the surface of the turntable 2 is made a second distance, an amount of ions reaching the wafer W in the third process area P3 is larger than that in the second process area P2 due to the second distance that is shorter than the first distance. Hence, an amount of radicals reaching the wafer W in the third process area P3 is larger than that in the second process area P2.

The first distance between the first plasma generator 81a and the surface of the turntable 2 and the second distance between the second plasma generator 81b and the surface of the turntable 2 can be set to various values as long as the first distance is longer than the second distance. For example, the first distance may be set in a range of 80 mm to 150 mm, and the second distance may be set greater than or equal to 20 mm but less than 80 mm. However, the distances may be changed depending on the intended purpose, and are not limited to the above values.

Other components of the film deposition apparatus according to one embodiment are described below again.

As illustrated in FIG. 2, a side ring 100 that forms a cover body is arranged at a position slightly lower than the turntable 2 and at an outer edge side of the turntable 2. Exhaust openings 61 and 62 are formed in an upper surface of the side ring 100 at two locations apart from each other in the circumferential direction. In other words, two exhaust ports are formed in a bottom surface of the vacuum chamber 1, and the exhaust openings 61 and 62 are formed at locations corresponding to the exhaust ports in the side ring 100.

In the present specification, one of the exhaust openings 61 and 62 is referred to as a first opening 61 and the other one is referred to as a second opening 62. Here, the first exhaust opening 61 is formed between the separation gas nozzle 42 and the first plasma generator 81a located downstream of the separation gas nozzle 42 in the rotational direction of the turntable 2. Furthermore, the second exhaust opening 62 is formed between the second plasma generator 81b and the separation area D located downstream of the plasma generator 81b in the rotational direction of the turntable 2.

The first exhaust opening 61 is to evacuate the first process gas and the separation gas, and the second exhaust opening 62 is to evacuate the plasma processing gas and the separation gas. Each of the first exhaust opening 61 and the second exhaust opening 62 is, as illustrated in FIG. 1, connected to an evacuation mechanism such as a vacuum pump 64 through an evacuation pipe 63 including a pressure controller 65 such as a butterfly valve.

As described above, because the housings 90 are arranged from the central area C side to the outer peripheral side, a gas flowing from the upstream side in the rotational direction of the turntable 2 to the second and third process areas P2 and P3 may be blocked from going to the evacuation opening 62 by the housings 90. In response to this, a groove-like gas flow passage 101 (see FIGS. 1 and 2) is formed in the upper surface of the side ring 100 on the outer edge side of the housing 90 to allow the gas to flow therethrough.

As shown in FIG. 1, in the center portion on the lower surface of the ceiling plate 11, a protrusion portion 5 is provided that is formed into an approximately ring-like shape along the circumferential direction continuing from a portion close to the central area C of the convex portion 4 so as to have a lower surface formed as high as the lower surface of the convex portion 4 (ceiling surface 44). A labyrinth structure 110 is provided at a location closer to the rotational center of the turntable 2 than the protrusion portion 5 and above the core portion 21 to suppress the various gases from mixing with each other in the center area C.

As discussed above, because the housings 90 are formed even in a position close to the central area C, a portion above the turntable 2 of the core portion 21 supporting the central portion of the turntable 2 is formed in an area close to the rotational center to avoid interfering with the housing 90. Due to this, the various gases are more likely to mix with each other in an area close to the central area C than an area close to the outer periphery. Hence, by forming the labyrinth structure portion 110 above the core portion 21, a flow path can be made longer to be able to prevent the gases from mixing with each other.

More specifically, the labyrinth structure portion 110 has a wall part vertically extending from the turntable 2 toward the ceiling plate 11 and a wall part vertically extending from the ceiling plate 11 toward the turntable 2. The wall parts are formed along the circumferential direction, respectively, and are arranged alternately in the radial direction of the turntable 2. In the labyrinth structure portion 110, for example, the first process gas discharged from the source gas nozzle 31 and heading for the central area C needs to go through the labyrinth structure portion 110. Due to this, the first process gas decreases in speed with the decreasing the distance from the central area C and becomes unlikely to diffuse. As a result, the process gas is pushed back by the separation gas supplied to the central area C, before the process gas reaches the central area C. Moreover, the labyrinth structure portion 110 makes other gases likely to head for the central area C difficult to reach the central area C in the same way. This prevents the process gases from mixing with each other in the central area C.

As illustrated in FIG. 1, a heater unit 7 that is a heating mechanism is provided in a space between the turntable 2 and the bottom part 14 of the vacuum chamber 1. The heater unit 7 is configured to be able to heat the wafer W on the turntable 2 through the turntable 2 up to, for example, a range from room temperature to about 760 degrees C. Furthermore, as illustrated in FIG. 1, a side cover member 71a is provided on a lateral side of the heater unit 7. An upper covering member 7a is provided so as to cover above the heater unit 7. In addition, purge gas supply pipes 73 for purging a space in which the heater unit 7 is provided are provided in the bottom part 14 of the vacuum chamber 1 under the heater unit 7 at multiple locations along the circumferential direction.

As illustrated in FIG. 2, a transfer opening 15 is formed in the side wall of the vacuum chamber 1 to transfer the wafer W. The transfer opening 15 is configured to be hermetically openable and closable by a gate valve G.

The wafer W is transferred between the concave portion 24 of the turntable 2 and the transfer arm 10 that is not illustrated in the drawings at a position where the concave portion 24 of the turntable 2 faces the transfer opening 15. Accordingly, lift pins and an elevating mechanism that are not illustrated in the drawings are provided at positions under the turntable 2 corresponding to the transferring position to lift the wafer W from the back surface by penetrating through the concave portion 24.

Moreover, as illustrated in FIG. 1, a controller 120 constituted of a computer to control operation of the whole apparatus is provided in the film deposition apparatus according to the present embodiment. A program to implement the substrate process described later is stored in a memory of the controller 120. This memory stores the program to perform the substrate process described later. This program is constituted of instructions of step groups to cause the apparatus to implement operations described later, and is installed into the controller 120 from a memory unit 121 that is a storage medium such as a hard disk, a compact disc, a magnetic optical disk, a memory card and a flexible disk.

[Film Deposition Method]

Next, a film deposition method according to an embodiment of the present disclosure is described below. The film deposition method according to an embodiment of the present disclosure can be implemented by using a variety of film deposition apparatuses as long as such film deposition apparatuses are capable of depositing films by ALD (Atomic Layer Deposition) or MLD (Molecular Layer Deposition). In the present embodiment, an example of performing the film deposition method using the above-described turntable type film deposition apparatus is described below.

An example is described below in which the first distance between the first plasma generator 81a and the turntable 2 in the second process area P2 where a first plasma process is performed is set longer than the second distance between the second plasma generator 81b and the turntable 2 in the third process area P3 where a second plasma process is performed. Moreover, an example of using DCS (SiH₂Cl₂, Dichlorosilane) as a source gas supplied from the source gas nozzle 31, a mixed gas of NH₃, Ar, and H₂ as a first plasma processing gas supplied from the first plasma processing gas nozzle 32, and a mixed gas of NH₃, N₂, and Ar as a second plasma processing gas supplied from the second plasma processing gas nozzle 33, is described below. However, the above-mentioned gases are cited as examples, and various kinds of Si-containing gases, various kinds of nitriding gases, and various kinds of treatment gases containing both NH₃ and N₂ can be used as the source gas, the first plasma processing gas, and the second plasma processing gas, respectively.

In the present embodiment, a nitriding gas that contains NH₃ but does not contain N₂ is used as the first plasma processing gas. A treatment gas that contains NH₃ and N₂ is used as the second plasma processing gas. To begin with, the reasons for using such gases are described.

In the plasma, when NH₃ and N₂ exist as individual gases, reversible reactions occur as indicated by the following expressions (1) and (2).

NH₃ [symbol] NH₂*+H* (1)

N₂ [symbol] 2N* (2)

When two gases exist in plasma, by reacting N* to H*, NH* and NH₂* are both generated as indicated by the following expressions (3) to (5). The nitriding power is increased and the reversible reactions of the expressions (1) and (2) are prevented.

N*+H*→NH* (3)

NH*+H*→NH₂* (4)

NH₂*+H*→NH₃ (5)

As indicated by expression (6), N₂ is added to HN₃ to be activated by plasma. Consequently, this acts to increase the nitriding power.

2NH₃+N₂ [symbol] 2NH₂*+2NH* (6)

By utilizing such a mechanism, in the present embodiment, a mixed gas of NH₃ and N₂ is used as the second plasma processing gas for modification to increase the nitriding power and improve the film quality.

In a case where N₂ reaches a certain concentration or more, however, NH₃ serving as a nitriding gas is diluted too much and NH₃ also serving as a nitriding source becomes insufficient. To prevent this, appropriate flow rates of NH₃ and N₂ need to be found. In the following, the film deposition method in an embodiment of the present disclosure is described together with such appropriate flow rates.

To bring the wafer W into the above-described film deposition apparatus, the gate valve G is opened first. Subsequently, while rotating the turntable 2 intermittently, the wafer W is placed on the turntable 2 by the transfer arm 10 through the transfer opening 15.

Then, the gate valve G is closed. A heater unit 7 heats the wafer W to a given temperature. The temperature of the wafer W may be set at an appropriate value depending on the intended use, may be set at a range of between 300 degrees C. and 600 degrees C., or may be set at, for example, about 400 degrees C.

Subsequently, DCS that is the source gas is supplied from the first process gas nozzle 31 at a given flow rate, and the first and second plasma processing gases are respectively supplied from the first and second plasma processing gas nozzles 32 and 34 at given flow rates. Here, the first plasma processing gas is a mixed gas of NH₃, Ar, and H₂, and the second plasma processing gas is a mixed gas of NH₃, N₂, and Ar. The first plasma processing gas is a nitriding gas for reacting to the Si-containing gas adsorbed on the surface of the wafer W and for depositing a molecular layer of SiN film on the surface of the wafer W. The second plasma processing gas is a treatment gas for further nitriding the SiN film deposited on the surface of the wafer W and improving the film quality of the SiN film. The treatment gas is a gas that leads to the reaction in the above expression (6), and has an effect of improving the nitriding power.

The pressure controller 65 controls the inside of the vacuum chamber 1 at a given pressure. In each of the plasma generators 81a and 81b, a high-frequency power with a given output is applied to the antenna 83. Here, the pressure may be set at an approximate value for intended use, may be set at a range of between 0.2 Torr and 2.0 Torr, or may be set at, for example, about 0.75 Torr.

The following description is given with reference to FIG. 2. On the surface of the wafer W, DCS that is the source gas (Si-containing gas) is adsorbed in the first process area P1 by the rotation of the turntable 2. The wafer W on which the first process gas is adsorbed is caused to pass through the separation area D by the rotation of the turntable 2. In the separation area D, the separation gas is supplied to the surface of the wafer W and unnecessary physical adsorptions relating to the first process gas are removed.

The wafer W then reaches the second process area P2 by the rotation of the turntable 2. In the second process area P2, the first plasma processing gas (NH₃-containing gas) supplied from the first plasma processing gas nozzle 32 is activated by plasma. DCS is nitrided by NH₂*, and then a silicon nitride film (SiN film) is deposited on the surface of the wafer W.

Here, various gasses can be used as the first plasma processing gas, as long as the gas is a nitriding gas containing NH₃. For example, a mixed gas containing Ar, NH₃, and H₂ may be used as the first plasma processing gas. Contained amounts and a flow rate ratio of Ar, NH₃, and H₂ may be varied depending on the intended use. For example, a mixed gas containing 2000 sccm of Ar, 300 sccm of NH₃, and 600 sccm of H₂ may be used. The first plasma processing gas is configured to sufficiently supply NH₃, which is a nitriding source, in consideration of nitriding Si components adsorbed on the surface of the wafer W. Hence, the first plasma processing gas does not contain N₂. The first plasma generator 81a is installed at a position higher than the position of the second plasma generator 81b, so that NH₂* to which NH₃ has been converted to plasma fully spreads over the whole surface of the wafer W. Since NH₂* has a broadly-diffusing characteristic, NH₂* can be suited for fulfilling such a role.

Generally speaking, ions and radicals are known as active species generated by plasma of the plasma processing gas. Ions mainly contribute to a nitride film modification process, and radicals mainly contribute to a nitride film deposition process. Ions are shorter in life than radicals. Therefore, by making the distance between each of the plasma generators 81a and 81b and the turntable 2 longer, ion energy reaching the wafer W is largely reduced.

In the second process area P2, the first distance between the first plasma generator 81a and the turntable 2 is set longer than the second distance. Such a comparatively long first distance greatly reduces the ions reaching the wafer W in the second process area P2, and the radicals are mainly supplied to the wafer W. That is to say, in the second process area P2, the first process gas on the wafer W is (initially) nitrided by plasma with comparatively small ion energy, and one or multiple molecular layers of nitride films that are thin-film components are formed in a layer-by-layer manner. Such one or multiple nitride films that have been formed are modified by plasma to some extent.

In the initial stage of the film deposition process, active species have a great influence on the wafer W. When plasma with great ion energy is used, for example, the wafer itself might be nitrided. Also in this regard, in the process in the second process area P2, the plasma process can be performed at first by the plasma with comparatively small ion energy.

The first distance is not particularly limited, but may be set in a range of between 80 mm and 150 mm, or may be set at 90 mm, for example, in consideration of depositing a nitride film on the wafer W in an effective manner by the plasma with comparatively small ion energy.

The wafer W that has passed through the second process area P2 reaches the third process area P3 by the rotation of the turntable 2, In the third process area P3, the second plasma processing gas supplied from the second plasma processing gas nozzle 33 is activated by plasma. The SiN film is further nitrided and the deposited SiN film is modified.

Here, various gasses can be used as the second plasma processing gas, as long as the gas is a treatment gas containing both NH₃ and N₂. For example, the mixed gas containing Ar, NH₃, and N₂ may be used as the second plasma processing gas. The contained amounts (flow rates) and the flow rate ratio of Ar, NH₃, and N₂ may be varied depending on the intended use. However, regarding a flow rate ratio of NH₃ to N₂ᵣ N₂ can be set at a flow rate higher than the flow rate of NH₃. Specifically, N₂ can be set at a flow rate twice or more the flow rate of NH₃. Further, N₂ can be set at a flow rate three times or more the flow rate of NH₃. For example, when the flow rate of Ar is set at 2000 sccm, the flow rate ratio of NH₃ (sccm)/N₂ (sccm) can be set at 600/1400, 500/1500, 300/1700, or 200/1800. Although working examples will be described later, among the above-described flow rate ratios, when NH₃/N₂=300/1700 was satisfied, film deposition was enabled with most preferable uniformity across the surface of the wafer. In this manner, regarding the flow rate ratio of NH₃/N₂ in the second plasma processing gas, the contained amount of N₂ can be three times or more as much as NH₃.

By supplying a mixed gas containing NH₃ and N₂ at such a flow rate ratio from the second plasma processing gas nozzle 33 to activate the mixed gas with the plasma generated by the second plasma generator 81b, the reaction that has been described with the above expression (6) can be developed and the nitriding power can be improved. N₂ plasma is short in life, but is high in energy. In addition, N₂ plasma has characteristics of being less likely to diffuse and concentrating under the antenna 83. The antenna 83 of the second plasma generator 81b is formed to extend longer than the edges of the wafers W in the radial direction. Thus, NH₂* and NH* can be concentrated under the antenna 83, and the SiN films at the edges of the wafers W in the radial direction can be sufficiently nitrided. This improves the uniformity of the SiN film across the surface of the wafers W.

In the third process area P3, the second distance between the second plasma generator 81b and the surface of the turntable 2 is set shorter than the above-described first distance. Since the second distance is shorter than the first distance, the amount of ions reaching the wafer W in the third process area P3 is larger than the amount of ions reaching the wafer W in the second process area P2. It is to be noted that the amount of radicals reaching the wafer W in the third process area P3 is also larger than the amount of radicals reaching the wafer W in the second process area P2. Therefore, in the third process area P3, the first process gas on the wafer W is nitrided by the plasma with comparatively large ion energy and with high-density radicals. The formed nitride film is modified in a more effective manner than the film modified in the second process area P2.

As long as the second distance is shorter than the first distance, the second distance may not be particularly limited. In consideration of modifying the nitride film in a more effective manner, the second distance may be set at greater than or equal to 20 mm but less than 80 mm. The second distance may be set at 60 mm (in height), for example.

The plasma-treated wafer W passes through the separation area D by the rotation of the turntable 2. The separation area D is an area for separating the first process area P1 from the third process area P3 to prevent unnecessary nitriding gas or treatment gas from entering the first process area P1.

In the present embodiment, by continuously rotating the turntable 2, a process of adsorbing a source gas (Si-containing gas) on the surface of the wafer W, nitriding a source gas component (Si) adsorbed on the surface of the wafer W, and modifying a reaction product (SiN) by plasma is repeated in this order multiple times. That is, a film deposition process by the ALD method and a film modification process for the deposited film are repeated multiple times by the rotation of the turntable 2.

The separation areas D are respectively arranged between the first and second process areas P1 and P2 on both sides in the circumferential direction of the turntable 2 in the film deposition apparatus according to the present embodiment. Thus, in the separation area D, the source gas and the plasma processing gas go toward the exhaust openings 61 and 62, while being prevented from mixing with each other.

### WORKING EXAMPLES

Next, working examples used for performing a film deposition method according to embodiments of the present disclosure will be described. A film deposition apparatus used in the working examples was an ALD film deposition apparatus of turntable type in which two plasma generators 81a and 81b were installed.

The temperature of the wafer W in the vacuum chamber 1 was set at 400 degrees C. The pressure in the vacuum chamber 1 was set at 0.75 Torr. The rotational rate of the turntable 2 was set at 10 rpm. In the second process area P2, the distance between the first plasma generator 81a configured to supply the first plasma processing gas and the turntable 2 was set at 90 mm. In the third process area P3, the distance between the second plasma generator 81b configured to supply the second plasma processing gas and the turntable 2 was set at 60 mm. The source gas supplied from the source gas nozzle 31 was DCS, which is a Si-containing gas, and the flow rate of the source gas was set at 1000 sccm. The nitriding gas supplied from the first plasma processing gas nozzle 32 was a mixed gas of NH₃, Ar, and H₂. The flow rate of NH₃ was set at 300 sccm. The flow rate of Ar was set at 2000 sccm. The flow rate of H₂ was set at 600 sccm. These settings were fixed conditions.

The treatment gas supplied from the second plasma processing gas nozzle 33 was a mixed gas of NH₃, Ar, and H₂. The flow rate of Ar was fixed at 2000 sccm, but the flow rates of NH₃ (sccm) and N₂ (sccm) were varied.

In the comparative example, NH₃ (sccm)/N₂ (sccm)=2000/0. This setting is for a modification process without adding N₂ᵣ which has conventionally been performed.

In the working example 1, NH₃ (sccm)/N₂ (sccm)=1500/500. In the working example 2, NH₃ (sccm)/N₂ (sccm)=1000/1000. In the working example 3, NH₃ (sccm)/N₂ (sccm)=500/1500. In the working example 4, NH₃ (sccm)/N₂ (sccm)=300/1700. In the working example 5, NH₃ (sccm)/N₂ (sccm)=200/1800. In the reference example, NH₃ (sccm)/N₂ (sccm)=0/2000. In the reference example, N₂ is contained but NH₃ is not contained. That is, a mixed gas of NH₃ and N₂ was not used in the reference example. This is the reason the expression of reference example was used, instead of working example.

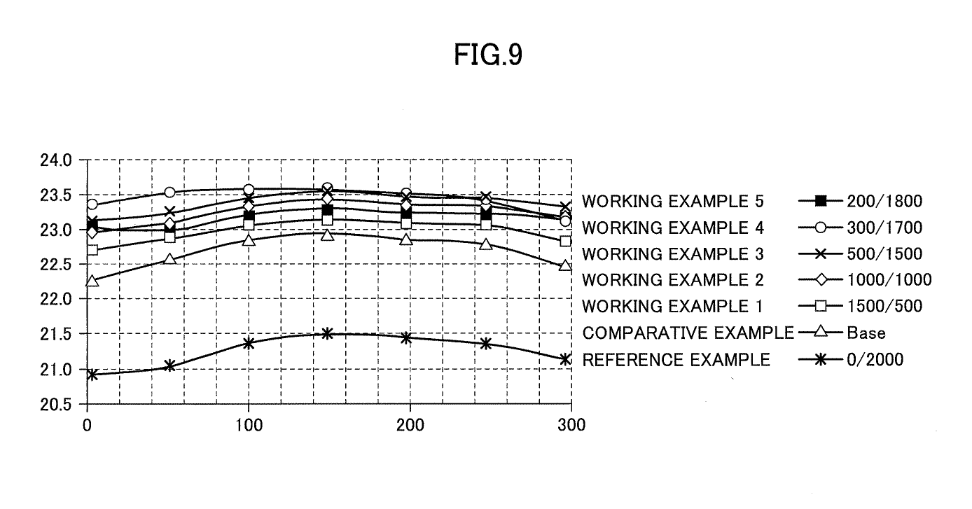

FIG. 9 is a diagram showing results, in which the film deposition method in the working examples 1 to 5, the comparative example, and the reference example were performed, on X axis that is a lateral axis passing through the center of the wafer W approximately parallel to a rotational direction of the turntable 2. In FIG. 9, the horizontal axis represents position on X axis on the wafer W, and the vertical axis represents film thickness of the SiN film.

As shown in FIG. 9, the film thickness was greatest in the working example 4 where NH₃ (sccm)/N₂ (sccm)=300/1700, and preferable uniformity was available. In the comparative example where N₂ was not added, the film thickness was smaller than the film thicknesses of the working examples 1 to 5. In the reference example where NH₃ was not contained, the film thickness was further smaller than the film thickness of the comparative example. Accordingly, FIG. 9 indicated that all of the working examples 1 to 5 had better uniformity than the uniformity of the comparative example and the reference example. Among the working examples 1 to 5, the working example 4 where NH₃ (sccm)/N₂ (sccm)=300/1700 indicated the most appropriate flow rate ratio.

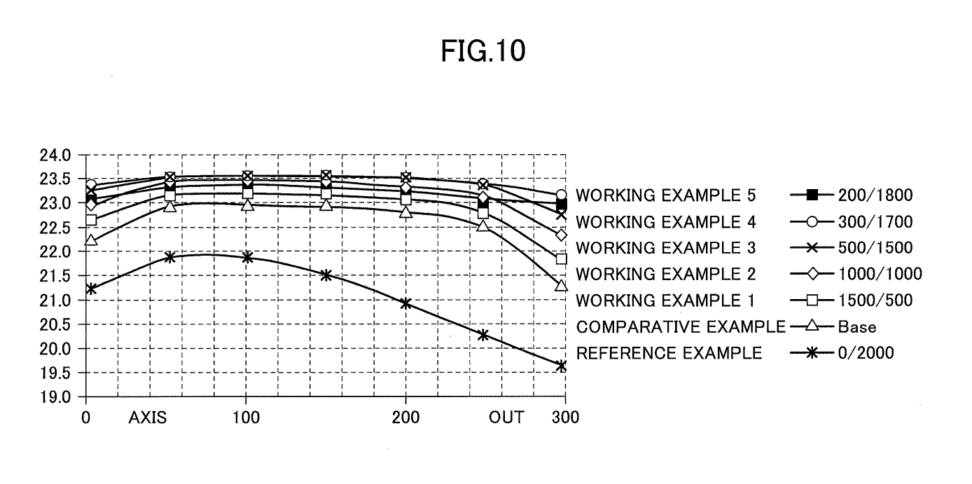

FIG. 10 is a diagram showing result, in which the film deposition methods in the working examples 1 to 5, the comparative example, and the reference example were performed, on Y axis that is a vertical axis passing through the center of the wafer W approximately parallel to the radial direction of the turntable 2. In FIG. 10, the horizontal axis represents position on Y axis on the wafer W, and the vertical axis represents film thickness of the SiN film.

As shown in FIG. 10, also on Y axis, the film thickness was greatest in the working example 4 where NH₃ (sccm)/N₂ (sccm)=300/1700, and excellent uniformity was also available. In the comparative example where N₂ was not added, the film thickness was smaller than the film thicknesses of the working examples 1 to 5. In the reference example where NH₃ was not contained, the film thickness was further smaller than the film thickness of the comparative example, similarly to FIG. 9. Accordingly, FIG. 10 indicated that all of the working examples 1 to 5 had better uniformity than the uniformity of the comparative example and the reference example. Among the working examples 1 to 5, the working example 4 where NH₃ (sccm)/N₂ (sccm)=300/1700 indicated the most appropriate flow rate ratio.

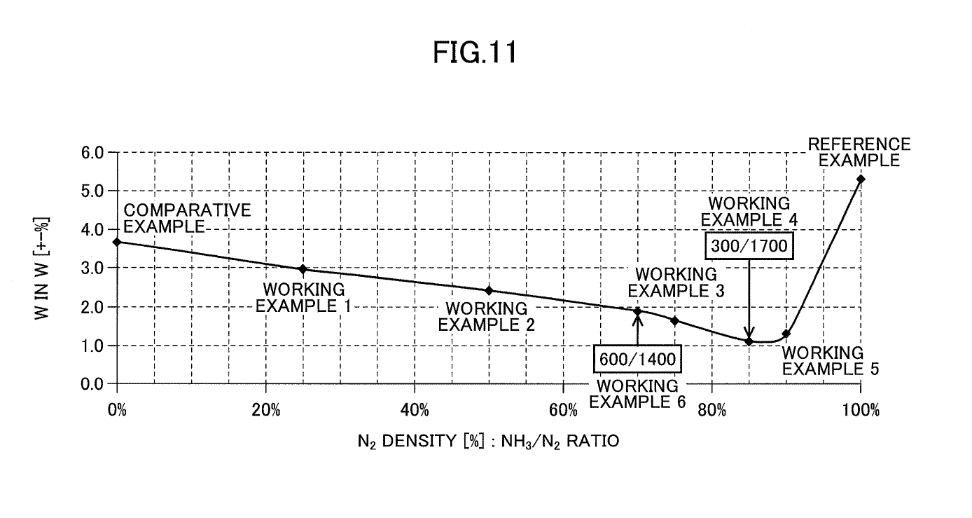

FIG. 11 is a diagram showing results, in which the film deposition methods in the working examples 1 to 5, the comparative example, and the reference example were performed, from a viewpoint of uniformity across the surface of the wafer. In FIG. 11, the horizontal axis represents N₂ concentration (%). As getting closer to the right end, N₂ density is higher. The vertical axis represents uniformity of film thickness in the wafer W (±%). As getting closer to 0, the uniformity is better.

As shown in FIG. 11, the working example 4 where NH₃ (sccm)/N₂ (sccm)=300/1700 was most preferable in uniformity. Next, the working example 5 where NH₃ (sccm)/N₂ (sccm)=200/1800 was second-most preferable. Subsequently, the uniformity was gradually lowering in order of the working example 3 where NH₃ (sccm)/N₂ (sccm)=500/1500, a newly added working example 6 where NH₃ (sccm)/N₂ (sccm)=600/1400, the working example 2 where NH₃ (sccm)/N₂ (sccm)=1000/1000, and the working example 1 where NH₃ (sccm)/N₂ (sccm)=1500/500. The uniformity of the working examples 1 to 6 is all higher than the uniformity of the comparative example where NH₃ (sccm)/N₂ (sccm)=2000/0 and the reference example where NH₃ (sccm)/N₂ (sccm)=0/2000.

As described above, the working examples 1 to 6 were all better in uniformity of film thickness than the comparative example and reference example. Among these examples, the working example 4 where NH₃ (sccm)/N₂ (sccm)=300/1700 indicated the most appropriate uniformity. In other words, the mixed gas containing both NH₃ and N₂ can be used for the treatment gas serving as the second plasma processing gas. Further, the value suited for the preferable uniformity across the surface of the wafer was found at a given flow rate ratio where the flow rate of N₂ is higher than the flow rate of NH₃.

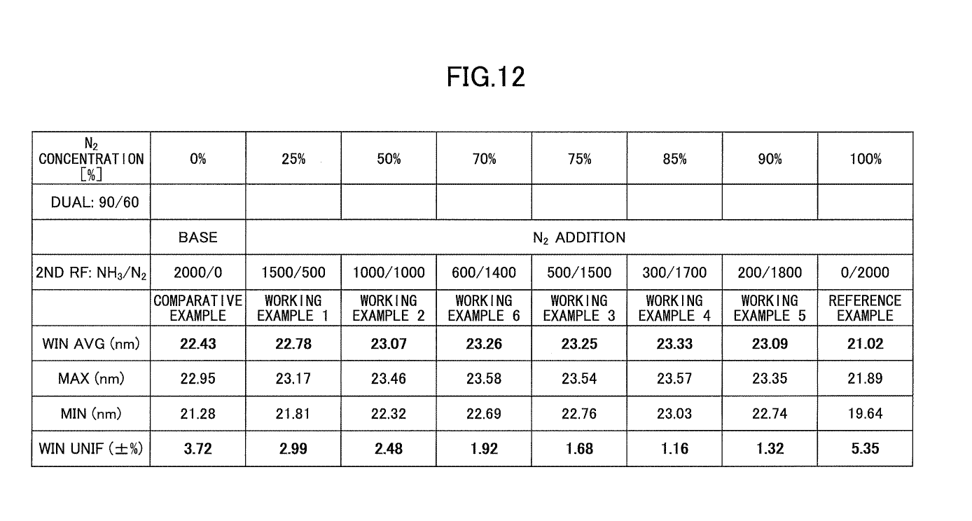

FIG. 12 is a diagram showing calculation results of the uniformity of the SiN film deposited on the wafer W in the working examples 1 to 6, the comparative example, and the reference example.

In FIG. 12, the average value of film thickness is represented by Win AVG (nm), the maximum value is represented by Max (nm), the minimum value is represented by Min (nm), and the uniformity is represented by Win Unif (±%). The calculation results of FIG. 12 were consistent with the results shown in FIG. 9 to FIG. 11. The working example 4 was ±1.16%, which was most preferable in uniformity. The working example 5 was ±1.32%, which was the second most preferable in uniformity. The working example 3 was ±1.68%, which was the third most preferable in uniformity. Further, the uniformity was gradually lowering in the order of ±1.92% in the working example 6, ±2.48% in the working example 2, and ±2.99% in the working example 1. These working examples 1 to 6 indicated better results than ±3.72% in the comparative example and ±5.35% in the reference example.

Regarding the film thickness, the working example 4 had the thickest film of 23.09 nm. The films available in the working examples 1 to 6 were thicker than the films in the comparative example and the reference example. However, unlike the uniformity, no big difference could be found in the film thickness, as a whole. According to the working examples 1 to 6, it is possible to improve the uniformity across the surface of the wafer, with making a given film thickness available.

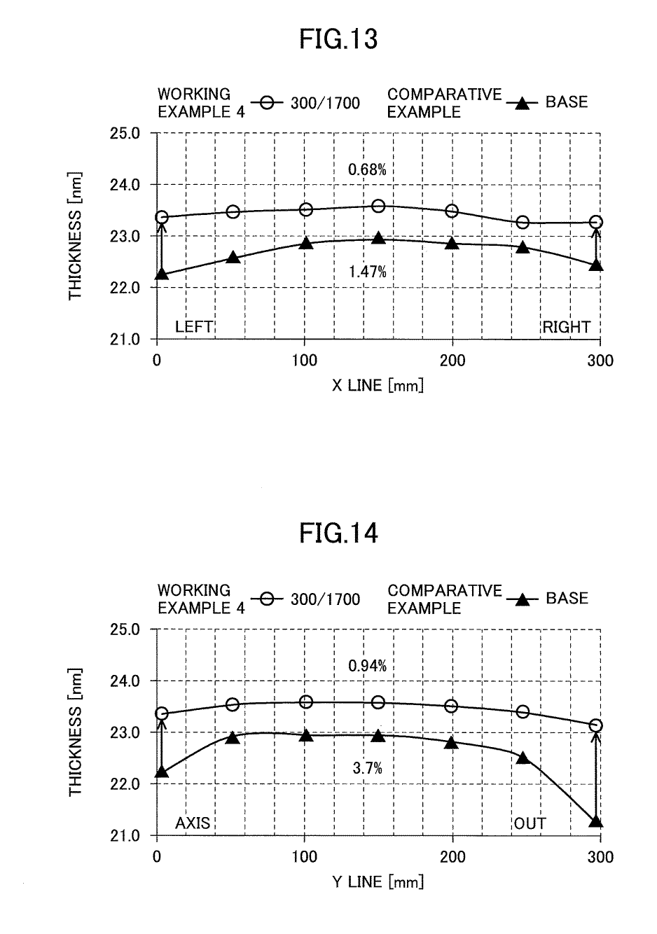

FIG. 13 is a diagram showing results of film thickness distributions on X axis in the working example 4 and the comparative example. As shown in FIG. 13, in the working example 4, the whole film thickness was improved and the film thicknesses at right and left edge portions were improved more than the film thickness of the comparative example. As a whole, the uniformity of film thickness was improved. That is to say, in the comparative example, the film thicknesses at right and left edge portions were largely lower than the film thickness in the central area on X axis, and the film thickness distribution of a mountain-like shape was shown. In contrast, in the working example 4, the film thicknesses at right and left edge portions were lower than the film thickness in the central area by only small amounts, and an approximately uniform film thickness distribution was shown as a whole.

According to the film deposition method in the working example 4 with optimal conditions, the film thickness uniformity was improved greatly as compared to the comparative example.

FIG. 14 is a diagram showing results of film thickness distributions on Y axis in the working example 4 and the comparative example. As shown in FIG. 14, similarly to X axis, in the working example 4, the whole film thickness was improved and the film thicknesses at axis-side and outer-side edge portions were improved more than the film thickness of the comparative example. As a whole, the uniformity of film thickness was improved. That is to say, in the comparative example, the film thicknesses at axis-side and outer-side edge portions were largely lower than the film thickness of the central area on Y axis, and the film thickness distribution of a mountain-like shape was shown. In contrast, in the working example 4, the film thicknesses at axis-side and outer-side edge portions were lower than the film thickness in the central area by only small amounts, and an approximately uniform film thickness distribution was shown as a whole. Specifically, the film thickness is greatly lowered at the outer side in the comparative example, whereas the film thickness was greatly improved at the outer side in the working example 4.

According to the film deposition method in the working example 4 with optimal conditions, it was exhibited that the film thickness uniformity can be improved greatly as compared to the comparative example.

Note that the conditions set for the examples 1 to 6 are examples, and better conditions for the working examples 1 to 6 can be found by additional experiments.

As described heretofore, in the film deposition method in one or more embodiments and in the working examples, by using an NH₃-containing gas as the first plasma processing gas and a mixed gas of NH₃ and N₂ as the second plasma processing gas, the uniformity of a nitriding film across the surface of the wafer can be improved. Further, in the second plasma processing gas, by making the contained ratio of N₂ higher than the contained ratio of NH₃ and founding out optimal conditions, the uniformity across the surface of the wafer can be further improved.

According to embodiments, it is possible to deposit films each having high uniformity across the surface of the wafer.

Embodiments and working examples have been described, but the present disclosure is not limited to these embodiments or working examples, but various variations and modifications may be made without departing from the scope of the present disclosure.

What is claimed is:

1. A film deposition method comprising steps of:
adsorbing a silicon-containing gas on a surface of a substrate, by supplying the silicon-containing gas to the surface of the substrate;
depositing a silicon nitride film, by supplying a nitriding gas to the surface of the substrate, while being activated by a first plasma, and nitriding the silicon-containing gas adsorbed on the surface of the substrate; and
modifying the silicon nitride film deposited on the surface of the substrate, by supplying a treatment gas containing NH₃ and N₂ at a given ratio to the surface of the substrate, while being activated by a second plasma.

2. The film deposition method according to claim 1, wherein N₂ is higher than NH₃ in the given ratio.

3. The film deposition method according to claim 2, wherein N₂ at least twice as much as NH₃ is included by the given ratio.

4. The film deposition method according to claim 3, wherein N₂ at least three times as much as NH₃ is included by the given ratio.

5. The film deposition method according to claim 1, wherein the nitriding gas is an NH₃-containing gas.

6. The film deposition method according to claim 5, wherein the nitriding gas is a gas that does not contain N₂.

7. The film deposition method according to claim 5, wherein the nitriding gas further contains Ar and H₂.

8. The film deposition method according to claim 1, wherein the treatment gas further contains Ar.

9. The film deposition method according to claim 1, wherein a position where the second plasma is generated is closer to the surface of the substrate than a position where the first plasma is generated.

10. The film deposition method according to claim 9, wherein the step of adsorbing the silicon-containing gas, the step of depositing the silicon nitride film, and the step of modifying the silicon nitride film are successively repeated to deposit the silicon nitride film to have a given thickness.

11. The film deposition method according to claim 10, further comprising the steps of:
supplying a purge gas to the surface of the substrate between the step of adsorbing the silicon-containing gas and the step of depositing the silicon nitride film; and
supplying the purge gas to the surface of the substrate between the step of modifying the silicon nitride film and the step of adsorbing the silicon-containing gas.

12. The film deposition method according to claim 11,
wherein the substrate is placed on a surface of a turntable provided in a process chamber along a circumferential direction,
wherein above the turntable in the process chamber, a silicon-containing gas supply area, a first purge gas supply area, a nitriding gas supply area, a treatment gas supply area, and a second purge gas supply area are successively provided along a rotational direction of the turntable, and
wherein the step of adsorbing the silicon-containing gas, the step of supplying the purge gas, the step of depositing the silicon nitride film, the step of modifying the silicon nitride film, and the step of supplying the purge gas are successively repeated, by rotating the turntable to cause the substrate to pass through the silicon-containing gas supply area, the first purge gas supply area, the nitriding gas supply area, the treatment gas supply area, and the second purge gas supply area.

13. The film deposition method according to claim 12,
wherein a first plasma generator is provided outside the process chamber above the nitriding gas supply area,
wherein a second plasma generator is provided outside the process chamber above the treatment gas supply area, and
wherein the second plasma generator is provided at a position lower than the first plasma generator.
